(19) United States
(12) Patent Application Publication
(10) Pub. No.: US 2021/0264702 A1
(43) Pub. Date: Aug. 26, 2021

(54) ACTIVE CONTAINER WITH DRONE DATA BRIDGING

(71) Applicant: Doubleday Acquisitions LLC, Moraine, OH (US)

(72) Inventors: Jonathan Neeld, Centerville, OH (US); Jeff Pepperworth, Moraine, OH (US)

(21) Appl. No.: 17/196,051

(22) Filed: Mar. 9, 2021

Related U.S. Application Data
(63) Continuation of application No. PCT/US20/67529, filed on Dec. 30, 2020.
(60) Provisional application No. 62/956,815, filed on Jan. 3, 2020.

(51) Int. Cl. G07C 9/00; G06F 13/16; G06F 13/40; G08B 5/22; G01S 19/01; G01K 1/024; G01R 31/371; G01R 31/382

(52) U.S. Cl. CPC G07C 9/00182; G06F 13/1668; G06F 13/4027; G08B 5/22; G01K 2215/00; G01K 1/024; G01R 31/371; G01R 31/382; G01S 19/01

(57) ABSTRACT

A system includes an active container with data bridging capabilities that uses short range wireless technology to communicate with nearby devices that have access to other data streams, such as GPS data and internet connectivity. When bridged with a provider, the container may have access to new data streams, or may be able to disable internal devices providing those same data streams to conserve power. In one implementation, an aerial drone is configured to function as a bridge provider to send data from the active container to a remote server during flight. In another implementation, a base station is adapted to receive an aerial drone after flight and is configured to function as a bridge provider to send data from the active container to a remote server after flight.

### CROSS REFERENCE TO RELATED APPLICATIONS

This is a continuation of PCT Application No. PCT/US20/67529, entitled “Active Container with Drone Data Bridging,” filed Dec. 30, 2020, which claims priority to U.S. Provisional Application No. 62/956,815, entitled “Active Container with Drone Data Bridging,” filed Jan. 3, 2020, the disclosures of which are incorporated by reference herein.

### FIELD

The disclosed technology pertains to a system for providing data bridging for active storage containers and environmentally controlled active storage containers.

### BACKGROUND

Goods shipped in containers may have thresholds for such factors as temperature, motion, humidity, and other characteristics of their storage environment. Fragile objects may require protection from contact with rigid objects or may require minimization of sudden forceful accelerations; medicines such as vaccines and food products may require a storage temperature within certain ranges; and electronics and paper goods may require a storage humidity within certain ranges. Deviations outside of acceptable ranges for these characteristics may affect the quality or efficacy of a shipped good, or in some cases may even completely ruin a good or make it harmful when used for its intended purpose. In some instances, goods may be appropriately shipped in passive containers which may be, for example, insulated and sealed containers having ice packs, vacuum, or cooled air stored inside. In other instances, passive features such as insulation and ice pack may not be sufficient, such as during lengthy transits in which ice will eventually melt, or with goods that may have a storage temperature range that is above freezing.

One limitation of many conventional active containers is that information gathered from sensors such as temperature sensors and GPS systems can only be used to retroactively identify problems rather than actively identify and resolve potential problems. While it may be useful to know that a medicine has been destroyed by being stored outsides of an acceptable temperature range when it arrives at its destination, it may be more desirable to alert the risk of storage outside of the acceptable range at the earliest opportunity, so that a responsible party can intervene and prevent or address the unacceptable storage conditions.

The above limitation is not easily addressed, since devices such as GPS systems or communication systems may not be available at all times during transit. For example, if an active container is placed in the cargo hold of an airplane for a lengthy flight, government or airplane regulations may require that long range wireless communication features such as GPS be disabled to prevent interference with critical flight systems. As another example, some warehouses or courier vehicles may be wireless communication dead zones due to their location or construction material, such that active containers stored within are incapable of sending and receiving long range wireless communications, which may prevent GPS data from being available while the container is present in such an area. As yet another example, the power requirements and weight of GPS systems or communication systems may be significant enough that they are not desirable for applications where power and weight are important factors, such as delivery of active containers by aerial drone.

What is needed, therefore, is an improved system for providing data bridging for active containers.

### BRIEF DESCRIPTION OF THE DRAWINGS

The drawings and detailed description that follow are intended to be merely illustrative and are not intended to limit the scope of the invention.

FIG. 1 is a flow diagram of an exemplary shipment cycle for an active container;

FIG. 2 is a schematic diagram of an exemplary system for active container data bridging;

FIG. 3 is a schematic diagram of an exemplary active container;

FIG. 4 is a flowchart showing an exemplary set of steps that an active container could perform to bridge available data connections;

FIG. 5 is a front elevation view of an exemplary keypad of an active container;

FIG. 6 is a flowchart showing an exemplary set of steps that an active container could perform to provide information on an active container via the exemplary keypad;

FIG. 7 is a schematic diagram of an exemplary system for drone data bridging;

FIG. 8 is a schematic diagram of an exemplary drone usable with the system of FIG. 7;

FIG. 9 is a schematic diagram of an exemplary base station usable with the system of FIG. 7;

FIG. 10 is a flowchart showing an exemplary set of steps that could be performed to provide data bridging to a remote network via a drone during transit;

FIG. 11 is a flowchart showing an exemplary set of steps that could be performed to provide data bridging to a remote network via a drone upon completion of transit; and

FIG. 12 is a flowchart showing an exemplary set of steps that could be performed to provide data bridging to a remote network via a base station or other local network.

### DETAILED DESCRIPTION

The novel technology that, for the purpose of illustration, is disclosed herein is described in the context of the shipment and storage of active containers. While the disclosed applications of this technology satisfy a long-felt but unmet need in the art of the shipment and storage of active containers, it should be understood that this technology is not limited to being implemented in the precise manners set forth herein, but could be implemented in other manners without undue experimentation by those of ordinary skill in the art in light of this disclosure. Accordingly, the examples set forth herein should be understood as being illustrative only and should not be treated as limiting.

One technology disclosed herein are active containers with data bridging that use one or more short range data transmission capabilities, such as Wi-Fi, Bluetooth, or a physical data connection, to connect to another system or device that is located proximately to the active container and that offers one or more data streams that may be used by the active container to produce analytics on its location, status of various systems, status of stored goods, and other information. This could include connecting with a local wireless network while stored in a warehouse in order to receive location data and exchange data with systems over the internet, connecting with a courier vehicle's GPS navigation and cellular data service via Bluetooth, connecting with an airplane's local wireless network to exchange data with systems over the internet, and other similar bridging techniques and circumstances.

By using data streams made available by such bridging techniques, an active container may disable independent GPS or cellular data systems to conserve power, or may continue to receive and exchange data with data streams when independent connection is unavailable (e.g., the active container does not have equipment allowing for independent connection or the active container is stored in an area where the connection is impossible) or prohibited for any reason. Operating in this manner, an active container may reduce or eliminate the number and duration of blind spots (i.e., points during transit where the active container is unable to receive or exchange information with data streams) that it experiences during a shipment cycle.

### I. EXEMPLARY ACTIVE CONTAINER WITH DATA BRIDGING AND METHODS

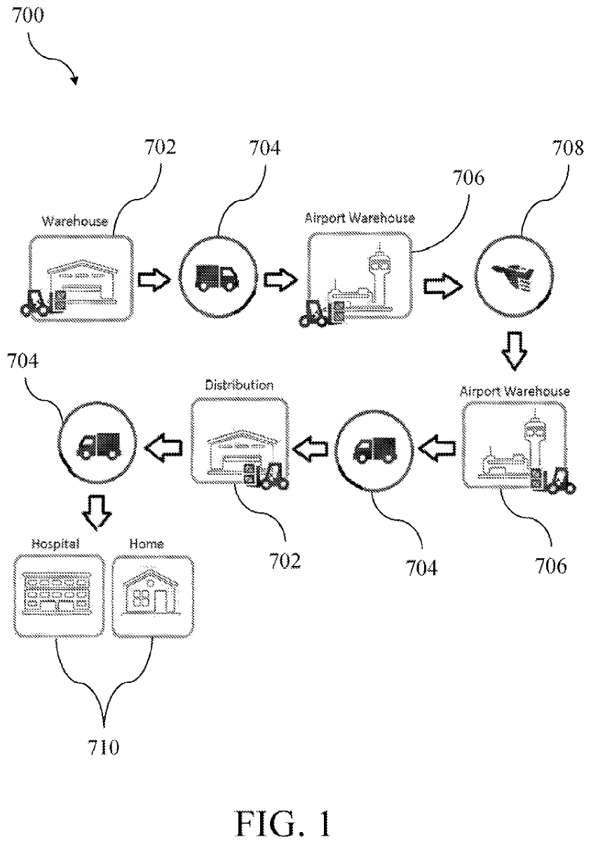

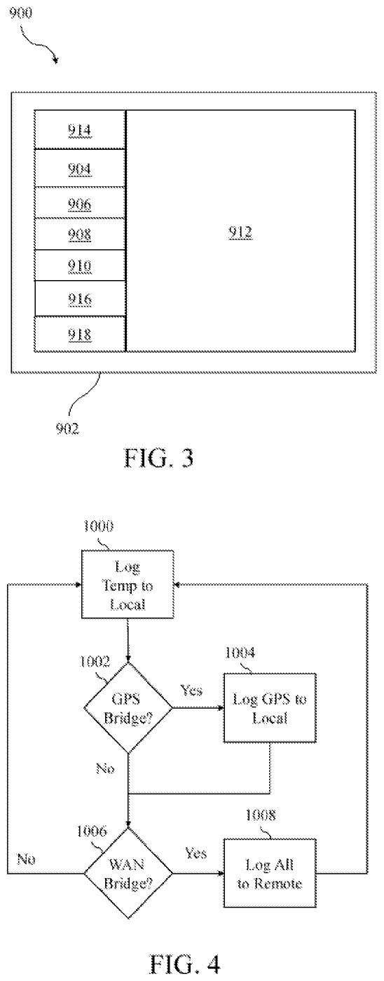

Turning now to the figures, FIG. 1 shows a flow diagram of an exemplary shipment cycle (700) that an active container (900), such as that shown in FIG. 3, may transit through. Active containers (900) may be used in a variety of contexts, and could include, for example, reusable containers owned by a party that sends or receives them, containers with limited reusability that are purchased and used for one or more shipments, and containers that may be rented or leased from a provider and used by a party that sends or receives them. During a shipment cycle an active container (900) may be stored in a variety of locations, including storage and distribution warehouses (702), courier vehicles (704), airport warehouses (706), airplanes (708), all before arriving at a destination (770). Each of these locations may have different characteristics and storage conditions that may impact an active container's (900) ability to track its location, report its location, or perform other tasks relating to inbound and outbound communications.

For example, some warehouses (702) may be constructed from concrete, metal, or other materials that alone or in combination with each other can block or reduce the quality of wireless data transmissions entering or exiting the interior of the structure. Courier vehicles (704) may also be constructed of metal or other materials that may passively block wireless transmissions to and from storage areas, and in some cases may even be purposefully shielded against such transmissions through the use of other passive or active wireless transmission blocking techniques. As with previous examples, airport warehouses (706) and airplanes (708) may be resistant to wireless transmissions due to materials or active shielding, and may additionally be regulated by statute or agreement prohibiting even unsuccessful attempts to wirelessly transmit data or even requiring that any device that is capable of wireless transmissions be completely powered off.

Active containers (900) can include devices that send or receive data. This could include location tracking systems (908) that receive GPS data from a satellite and provide that location data to remote servers and devices in the form of tracking information, keypads (914) and security features that may remotely lock or unlock an active container (900) in response to communications from a remote server, battery (904) management systems that report a battery status and charge to remote servers, and other similar features.

For example, a tracking system (908) that can receive GPS or other location data in order to determine a present location, which may then be locally stored on a memory throughout a trip. Such information may be used to later recreate the path taken during a shipment or may be used to enable or disable various features of the active container (900) based on a geographic location of the container. This could include enabling or disabling certain types of wireless transmission when the active container (900) is in or near an airport, automatically locking the active container (900) when it is in certain storage areas or outside of a certain predicted route, or other similar actions. When the tracking system (908) is unable to independently resolve the active container's (900) location, because receipt of GPS data it is blocked, prohibited, or disabled to conserve power, such features may be unavailable.

As another example, some active containers (900) may regularly exchange data with remote systems. This could include reporting a present location to allow for real-time tracking of a shipment, reporting the temperature or humidity of goods stored within a storage compartment (912), reporting a battery (904) charge level, reporting attempts to access the container via a keypad (914), reporting the status of one or more active systems (906), which may include temperature and humidity control systems, and other information which may desirably be transmitted to a remote server and aggregated or otherwise used. Containers that exchange data with remote systems could include, for example, containers having active environment (e.g., temperature, humidity) control systems (e.g., integrated compressors or thermoelectric devices that can produce heat or cold and maintain or change a current temperature), containers having semi-active environmental control systems (e.g., containers that do not produce heat or cold during transit, but have materials and devices that help it to retain and maintain a starting temperature such as eutectic plates and circulation fans), and passively environmentally controlled containers (e.g., containers that rely solely on materials or passive mechanical features to maintain a starting temperature).

While the specific contents of the data that is produced and exchanged with containers having active, semi-active, and passive environmental control systems will vary, the teachings herein may be applied to each. Additionally, it should be understood that the active container (900) may have a controller such as a processor (918) configured to control one or more of the active systems (906), the tracking system (908), the communication devices (910), or other devices or components of the active container (900). The processor (918) may be a single processor operable to control or usable by one or more components of the active container (900) or may be multiple processors each accessible by or dedicated to one or more components. For example, in some implementations the processor (918) may comprise a main processor operable to control and exchange information with the tracking system (908) and the communication devices (910) and may also comprise a processor dedicated to or contained within the tracking system and configured to receive and interpret positioning signals, trigger events related to positioning signals, and other similar tasks. Other similar variations and implementations will be apparent to one of ordinary skill in the art in light of the disclosure herein.

Exchanges of information may be made via one or more communication or network devices (910) of the active container (900), which may include devices independently capable of communications with a remote server such as a cellular data modem, but may also include devices capable of bridging to other locally available data connections, such as Bluetooth, Wi-Fi, or other similar short range wireless technologies that may be installed within or mounted to the exterior of a case (902) of the active container (900), or wired communication options such as USB, Ethernet, or broadband over power. When the network devices (910) are unable to communicate with remote systems, because the communications are blocked, prohibited, or disabled to conserve power, such features may be unavailable.

An inability to receive or send certain types of data, whether because transmissions are fully or partially blocked, or because a device is shut off or prohibited from use, may impact one or more of the above described features of an active container (900). Even where full and independent connectivity is possible, it may be desirable to limit the use of such connectivity to devices that consume little power (e.g., low energy Bluetooth rather than long range cellular data) when possible, in order to conserve an active container's (900) limited battery (904) charge.

While independent communication with a remote server or device via a GPS receiver or cellular data modem may at times be prevented or prohibited, short-range wireless communications via Bluetooth, Wi-Fi or other technologies may avoid such prohibitions or may operate normally within a warehouse (702), courier vehicle (704), or airplane (708) rather than being blocked by a metal or concrete exterior surface. Establishing a local connection to a device that is capable of connection to a remote server effectively allows an active container (900) to bridge and use that data stream to maintain any features that rely on connection with a remote device when independent connection is unavailable or undesirable.

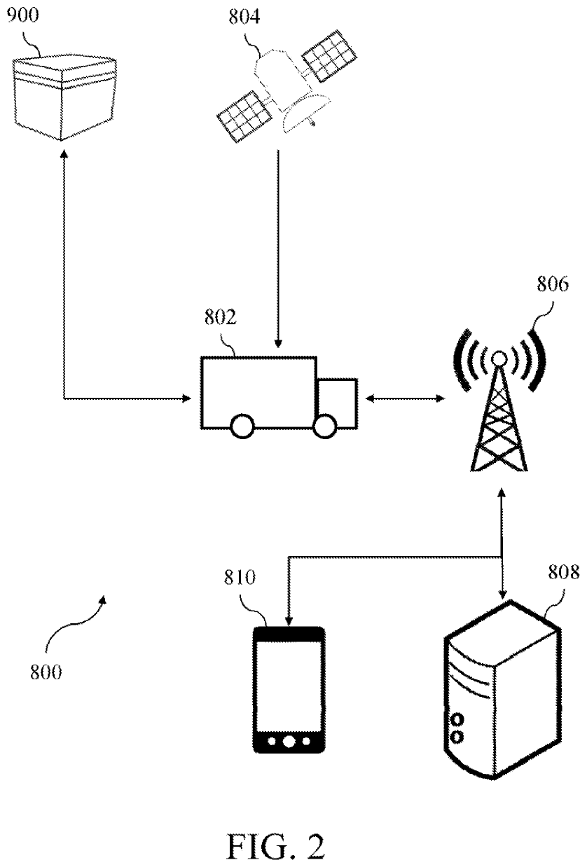

As an example, FIG. 2 shows a diagram of a system (800) capable of data bridging in order to maintain transmission and receipt of various data when wireless transmissions are prevented or prohibited. In the shown example, a bridge provider (802) may be, for example, a warehouse (702), courier vehicle (704), airplane (708), or other place that an active container (900) may be stored during a shipment cycle, and that also has access to one or more data streams needed by the active container (900), such as GPS data (804) or wide area network internet connectivity (806) via a cellular data modem, which may allow communication with remote devices such as a server (808) or mobile device (810). Bridge providers (802) may provide data streams that may be bridged in a variety of ways. For example, in the case of a warehouse (702) or airport warehouse (706), wireless communications from within the warehouse directed at destinations outside of the warehouse (702) may be fully or partially blocked by cement and metal materials used to construct the warehouse (702).

However, computer systems within the warehouse (702) itself may have access to a wide area network (806) via an externally mounted antenna or cable. Receipt of GPS signals may also be unreliable within the warehouse, but a computer system within the warehouse (702) could store information that could be used to determine the warehouse (702) GPS location, or even the GPS location of an active container (900) stored in the warehouse (702). In this example, an active container (900) could use a Wi-Fi, Bluetooth, or other network device (910) to connect to a device or local area network available within the warehouse (702) in order to send and receive information with the warehouse (702) computer system. Establishing such a connection would allow the active container (900) to receive information indicating a current location and allow information, such as a record of its location, a record of the temperature and condition of goods, a battery charge, or other information to be exchanged with a server (808) or mobile device (810). Such information may be used to provide reassurance that the active container (900) will arrive in the expected time and condition, or to intervene if the provided information indicates that the active container (900) has been misplaced, or that an active system (906) or battery (904) has failed or will fail.

In an example where the bridge provider (802) is a courier vehicle (704), and independent communication with a GPS data stream (804) or a wide area network (806) is impossible, prohibited, not desirable, or otherwise unavailable for at least the reasons described above, the courier vehicle (704) itself may have integrated devices capable of receiving a GPS data stream (804) or communicating with a wide area network (806). This is frequently the case with vehicles used for high volume transit of packages and goods both for delivery to retail locations and delivery to homes and businesses, and even many personal vehicles are now equipped with GPS navigation and cellular data modems. Even where such devices are not integrated with a courier vehicle (804), a driver of a vehicle may have a mobile device having such capabilities, such as a mobile phone or a mobile hotspot. Where such capabilities are available, as with previous examples, the active container (900) may use a Wi-Fi, Bluetooth, or other network device (910) to connect to the bridge provider (802) (whether it is an integrated device of a courier vehicle (704) or a device possessed by a driver or occupant) and access GPS data streams (804) and wide area network data stream (806) via the bridge provider (802).

In examples where the bridge provider (802) is an airplane (708) the situation is similar, though airplanes may be more likely to prohibit certain types of wireless transmission. So, for example, Bluetooth or other short-range wireless options may be preferred options for bridging, while Wi-Fi, which typically has a longer range, may be prohibited or unavailable. Where an airplane (708) is the bridge provider (802), bridging may only be allowed at certain times during a flight, which may require that the network devices (910) power off when a sensor of the active container (900) such as an accelerometer or altimeter indicates that the airplane (708) is taking off or landing, or when a signal is received from the bridge provider (802) indicating that the network devices (910) should power off. It may also be the case for airplanes (708) or other bridge providers (802) that the network device (900) that is used to connect to the bridge provider (802) is a physical cable or other mechanical connection that is made when the active container (900) is placed at the bridge provider (802). Such a physical cable or other mechanical connection might additionally provide power, heating or cooling ventilation, and other resources that could benefit an active container (900) or allow it to reduce reliance on internal active systems (906) or batteries (904).

Turning now to FIG. 4, that figure shows a flowchart of a set of steps that may be performed by an active container (900) in order to utilize data streams from nearby bridge providers (802). The steps of FIG. 4 assume that the active container (900) does not have independent access to GPS and wide area network data streams, which may include such connectivity being blocked, prohibited, undesirable, or that the active container (900) is not equipped for independent GPS and wide area network access. In such a scenario, the active container (900) will locally log (1000) temperature, humidity, battery status, vibration or motion status, or other characteristics that it is configured to detect and determine to a memory (916) of the active container (900), which, for example, could be a component of the network device (910), tracking system (908), active systems (906), or a standalone memory (916) in communication with other components of the active container (900). Such information could be locally logged (1000) as it is generated, in compressed or encrypted form as may be desirable, and in any form or data structure that will allow the data to later be aggregated, graphed, or otherwise recreated as may be desirable for a particular application. If a GPS bridge becomes available (1002), such as may be the case when the active container (900) is in proximity with a bridge provider (802) that has access to a GPS data stream (804) or that is otherwise configured to provide location data, the active container (900) can connect to the bridge provider (802) via a network device (910) and begin receiving GPS information, or other information that might be available via the bridge provider (802), that can be locally logged (1004) to a memory (916) of the active container (900).

If a wide area network bridge becomes available (1006), such as may be the case when the active container (900) is in proximity with a bridge provider (802) that has access to a wide area network data stream (806), the active container (900) can connect to the bridge provider (802) via a network device (910) to access the wide area network data stream (806). The wide area network data stream (806) may be accessible through, for example, a warehouse (702) broadband internet connection, a courier vehicle (704) or airplane (708) cellular data connection, a mobile phone cellular data connection, or other similar devices or connections. When the active container (900) connects via a WAN bridge (1006), it may begin exchanging information with servers (808) and mobile devices (810), which could include providing information to those devices indicating the active container's (900) location and condition or other information that may be desirably logged (1008) to a remote device. Other types of information that may be logged locally and remotely and uses for that information will be apparent to those of ordinary skill in the art in light of the disclosure herein.

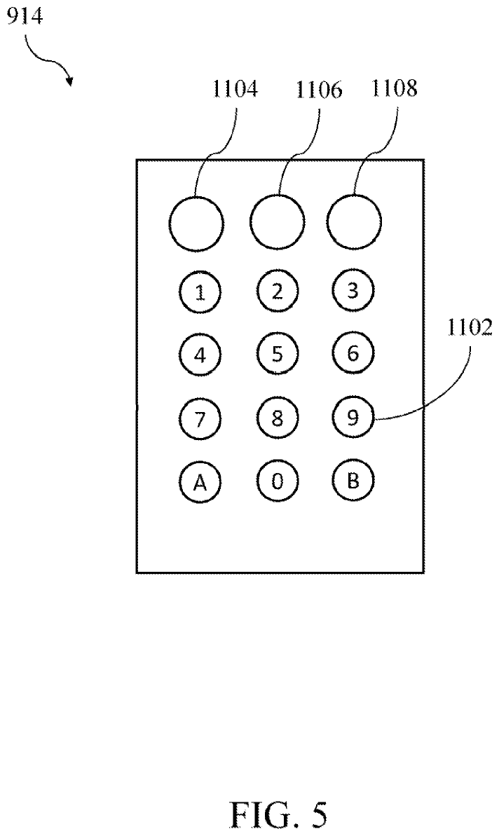

One component of the active container (900) that has been previously mentioned is the keypad (914), shown in FIG. 5. The keypad (914) has several features that may operate along with the data bridging capabilities that have been previously described. A set of buttons (1102) may be used by an operator to interact with the active container (900), and may allow a user to, for example, lock, unlock, or change configurations of the active container (900). The keypad may also have one or more indicators, including a critical indicator (1104), a safe indicator (1106), and a caution indicator (1108). The shown indicators (1104, 1106, 1108) may be, for example, light emitting diodes that may be activated to emit varying colors. A critical indicator (1104) may emit a red light to indicate, for example, a critical failure of some aspect of the active container (900) that may impact the usability of the goods stored therein. A safe indicator (1106) may be a light emitting diode capable of emitting, for example, a green light to indicate, for example, that the active container (900) is operating as expected, and that the good stored therein should be in their expected condition. A caution indicator (1108) may be a light emitting diode capable of emitting, for example, an orange or amber light to indicate, for example, that the active container (900) has a low risk error that is unlikely to impact the usability of goods stored therein, but that should be investigated.

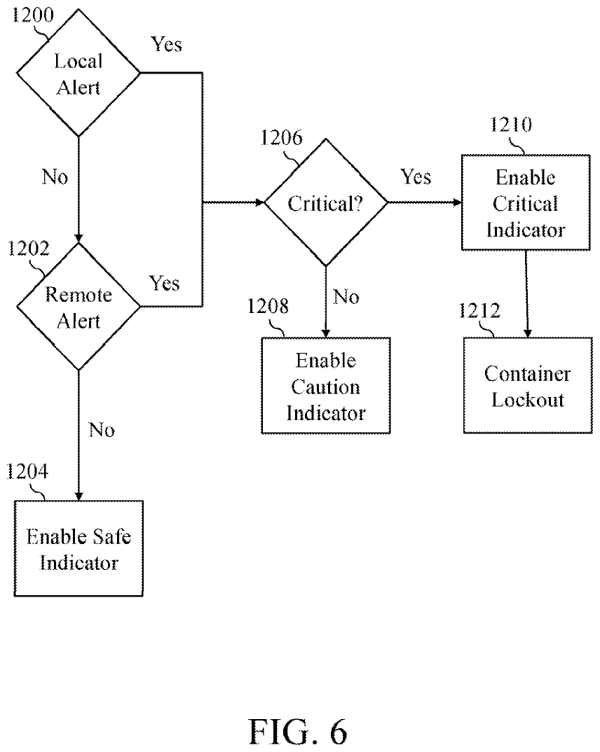

One or more indicator lights (1104, 1106, 1108) may be lighted by the active container (900) in some circumstances. FIG. 6 shows a flowchart of an exemplary set of steps that could be performed to light indicator lights of the keypad (914) in one set of circumstances. One or more systems or components of an active container may generate diagnostic messages and alerts during use. This could include, for example, a battery (904) low charge or malfunction, a failure or unpredictable behavior of an active system (906) such as the temperature management system, a temperature or humidity reading from a storage compartment (912) that is outside of the safe storage range for the goods therein, or other similar occurrences may generate local alerts (1200).

Remote alerts may also be generated (1202) when an active container (900) is in communication with a remote system such as a server (808). Remote alerts may occur (1202) when a server (808) or mobile device (810) provides information or instructions to the active container (900) that generate an alert. This could include, for example, an indication from the server (808) that the active container (900) was shipped to the wrong destination, that it contains the wrong goods, that the goods within the container were improperly packed or have been recalled by a manufacturer, that some information provided by the active container (900) indicates that the goods are unusable despite not generating a local alert (1200), or other similar situations where a determination is remotely made that the active container (900) should be placed into a certain alert mode.

Where no local or remote alert exists, or when a previous alert has been cleared or resolved, the keypad (914) safe indicator may be enabled (1204) to provide a visual indicator that the active container (900) is operating as expected and the goods contained therein were properly stored and maintained. After a local or remote alert has been generated, a determination may be made as to whether it is critical (1206) or not. This determination may be made by the system or component generating the alert and included in the electronic signal that generates the alert, may be determined at a remote server (808) and delivered as part of a remote alert, or may be determined by a processor (918) and memory (916) of the active container (900). A determination of whether an alert is critical or not (1206) may depend upon such factors as the goods stored within the storage compartment (912), the nature and severity of the alert, or other factors. For example, one alert may indicate that the temperature at which goods were stored in the active container (900) was 5% above the safe range for a period of 5 minutes. For some goods this may be a critical alert (1206), in which case the critical indicator would be enabled (1210) to visually alert someone that the goods inside should not be used, and may also cause the active container (900) to lockout (1212) and prevent attempts to access the storage compartment (912) via the keypad (914) without an access code or other remote authorization. The same set of circumstances might be determined as non-critical (1206) for different types of goods, in which case the caution indicator would be enabled (1208) to indicate that some abnormality occurred during shipment and further inquiry may be warranted, but that the goods may be accessed and used if necessary.

Other examples of situations which may generate alerts exist. For example, if an active container (900) is reported to be stolen, or if local or remotely available location data indicates that it is located outside of its expected route or was delivered to an incorrect destination, a local or remote alert may be generated (1200, 1202) and deemed to be critical (1206) in order to provide a critical warning indicator (1210) and lockout (1212) so that the contents of the storage compartment (912) are not easily accessed by someone who has mistakenly or maliciously taken possession of the active container (900). Such alerts may be triggered when, for example, an active container (900) disconnects from the bridge provider (802) outside of an expected geofenced area (e.g., where connection with the bridge provider (802) is lost while the active container (900) is more than 100 yards from the expected delivery destination), as this could indicate that the active container (900) was delivered to the wrong area, stolen, or is otherwise off its expected course. In such a circumstance, the keypad (914) may be configured to automatically lockout (1212) based upon being outside of the geofenced delivery area when bridge connection was lost, and may additionally be configured to automatically clear the lockout (1212) when a bridge connection is restored within the geofenced delivery area.

As another example, if a local or remote alert is generated (1200, 1202) indicating that a courier vehicle (704) that the active container (900) was within was involved in a sudden stop or traffic accident, as indicated by information provided from the bridge provider (802) or an accelerometer within the active container (900) for example, a caution light might be enabled (1208) to indicate that the goods are likely usable, but should be closely inspected for physical damage caused by jarring movements. Further examples will be apparent to one of ordinary skill in the art in light of the disclosure herein.

### II. EXEMPLARY DRONE DATA BRIDGING SYSTEM AND METHODS

While the system of FIG. 2 describes several data bridging systems and techniques involving bridge providers (802) such as courier vehicles, airplanes and storage areas, a data bridging system may also be implemented with features for data bridging with unmanned aerial vehicles, aerial drones, quadcopters, and devices and infrastructure related to the operation of such devices, which may be referred to generally as drones (e.g., aerial drones of varying styles) and base stations (e.g., a landing station, docking station, or other designated equipment that is a destination or origin of a drone). Drones may be configured to carry deliverable objects (e.g., a payload) from an origin to a destination, which may provide a number of advantages.

In some implementations, a drone may receive a payload at an origin base station and then, based upon manual configurations or automated instructions, fly to a destination base station or other destination point with the payload. In some implementations, payloads may be dropped at a destination so that the drone may return the origin base station or another location. In some implementations, the drone may remain at the destination until the payload is manually removed or some other acknowledgment of receipt is provided, and then may automatically proceed to another location or may be manually returned to its origin. Such implementations and others may advantageously minimize human involvement in the point-to-point transit of the payload and may also allow for efficient transit of payloads by avoiding ground traffic or by taking routes that are unavailable to ground traffic.

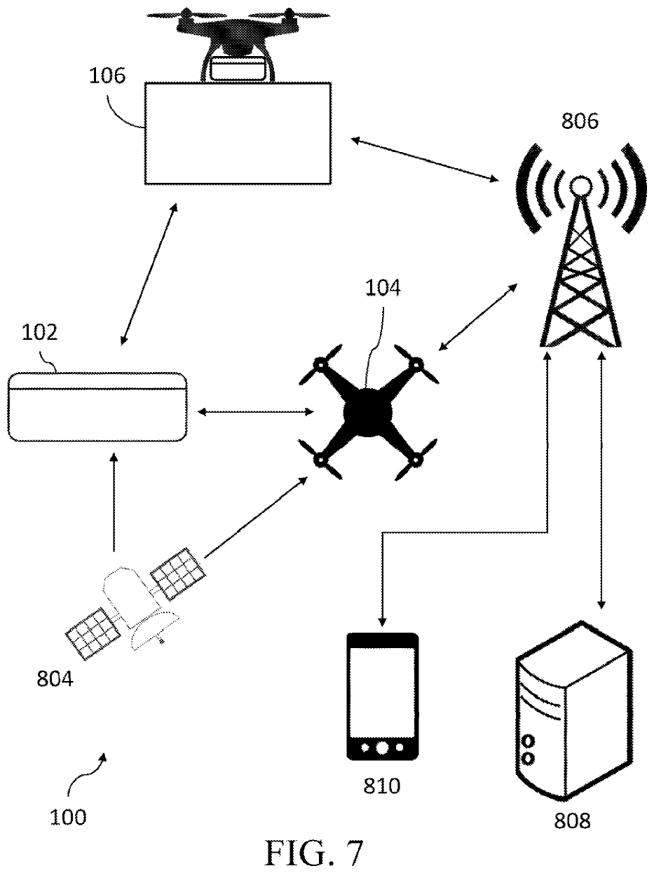

FIG. 7 shows a schematic diagram of an exemplary system (100) that provides data bridging during transit of active containers by unmanned vehicles, aerial drones, and other drones. An active container (102) may be an active container having one or more of the features of the active container (900) shown in FIG. 3. The active container (102) may have a size, shape, weight, and other characteristics that make it appropriate for being carried by a drone (104) in order to deliver goods held in a storage compartment (912) of the active container (102). The active container (102) may be coupled to the drone (104) with features such as mechanical locks, latches, or rails present on the case (902) that correspond to physical features of the drone (104) (e.g., the drone (104) may include a set of locking rails that support and immobilize a corresponding set of rails on the case (902)).

The active container (102) of FIG. 2 may include features and components such as location tracking systems (908), the keypad (914), the battery (904), the processor (918), communication devices (910), the memory (916), and active systems (906). One example of the active container (102) may include a lightweight insulated case (902) and storage compartment (912), a GPS receiver, a Bluetooth transceiver, passive cooling features such as ice packs or phase change materials, active cooling features such as a thermoelectric plate or air circulation fan directed at a passive cooling feature, a temperature sensor configured to provide temperatures in one or more areas of the storage compartment (912), and a storage device configured to store information from the GPS and temperature sensor.

An active container (102) such as that described above may not be capable of direct communication with the wide area network (806), as the communication devices (910) may not include cellular data capabilities. Alternately, such capabilities may be included, but may be limited during transit by the drone (104) (e.g., such as where wireless transmissions from the drone (104) may interfere with wireless transmissions from the active container (102), or may otherwise be advantageously avoided during transit (e.g., such as where the cellular data capabilities may be disabled in order to preserve battery power for maintaining the condition of the storage compartment (912)).

In some implementations where the active container (102) does not communicate with the wide area network (806) for any reason, the drone (104) itself may include such capabilities, and may communicate with the active container (102) via short range wireless communication (e.g., Bluetooth, wi-fi) in order to data bridge the active container (102) to the wide area network (106), as will be described in more detail below. Such an implementation may be advantageous because it allows data generated by the active container (102), such as temperature and location data, to be transmitted to a remote device such as the server (808) during transit in real-time, or in response to requests for status information associated with the active container (102).

As another example, where the active container (102) does not communicate with the wide area network (806) for any reason, a base station (106) may be capable of communicating with the wide area network (806), and may communicate with the active container (102) via short range wireless communication (e.g., Bluetooth, wi-fi) in order to data bridge the active container (102) to the wide area network (106), as will be described in more detail below. Such an implementation may be advantageous because it allows data generated by the active container (102) to be transmitted to a remote device such as the server (808) before and after transit, or at other times during transit when the active container (102) is within range of a base station (106) or another local bridge device. As a result, the data may be accessible and usable more quickly as compared to manually retrieving data from the memory (916) (e.g., by USB cable or other wired connection) when and if the active container (102) is returned to the sender.

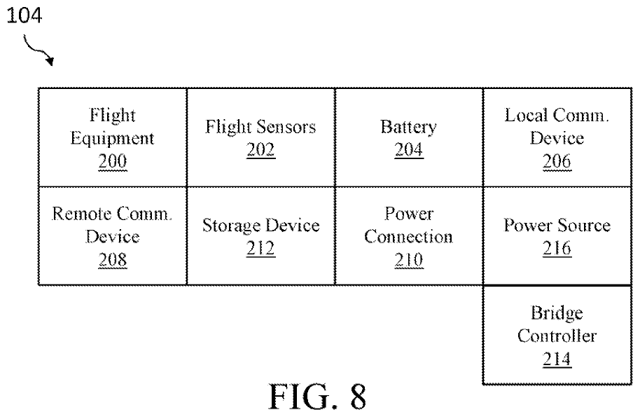

As described above, the drone (104) may provide data bridging capabilities to the active container (102) in order to improve availability of data. FIG. 8 shows a schematic diagram of an exemplary drone such as the drone (104). The drone (104) includes flight equipment (200) such as directional propellers and flight control systems, as well as flight sensors (202) such as accelerometers, GPS receivers, gyroscopes, and other sensors that produce information usable by the flight equipment (200) to navigate the drone (104). One or more batteries (204) power the drone (104) during flight and may also power devices that provide data bridging with the active container (102). Devices used during data bridging include a local communication device (206) which may be a short-range wireless transceiver (e.g., Bluetooth, wi-fi, NFC) or wired connection (e.g., USB, USB-C), a remote communication device (208) which may be a long-range wireless transceiver (e.g., cellular data network transceiver), a bridge controller (214) which may include a processor and memory configured to manage data bridging features, and a storage device (212) such as an electronic memory configured to store data generated by the flight sensors (202), data received from the active container (102), or both.

The drone (104) also includes one or more power connections (210) adapted to couple the drone (104) with another device in order to charge the battery (204) or to provide power to the attached device (e.g., such as where the active container (102) is coupled to the drone (104) via the power connection (210)). In some implementations, such as where the active container (102) is coupled to the drone (104) via USB, a single connection may allow for exchange of power and data between the devices. The drone (104) also includes a power source (216), which may be a secondary battery or flexible surface mounted solar panel. Where present, the power source (216) may be configured to provide power to the battery (204), the active container (102), or both.

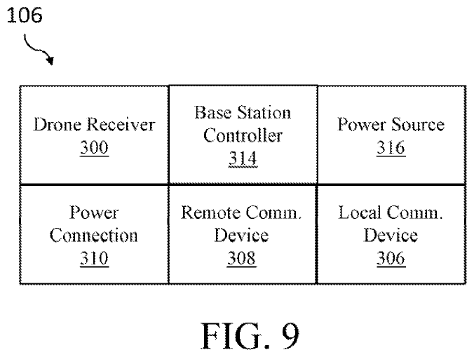

As another example of data bridging within the system (100), the base station (106) may provide data bridging capabilities to the active container (102) in order to improve availability of data. FIG. 9 is a schematic diagram of an exemplary base station such as the base station (106). The base station (106) includes a drone receiver (300) configured to receive a drone (e.g., the drone (104) or another drone) and the active container (102). In some implementations, the drone receiver (300) may be a surface upon which a drone rests before and after transit. In some implementations, the drone receiver (300) may include automated members that can, as an example, remove the active container (102) from a drone, cover or conceal the drone and/or the active container (102) in a storage area of the base station (106), and connect power and/or data cables to the drone, the active container (102), or both.

The base station (106) also includes a local communication device (306), having similar features and functions as the local communication device (206) of FIG. 8, and a remote communication device (308), having similar features and functions as the remote communication device (208). The local communication device (306) may be a wireless transceiver corresponding to a wireless capability of the active container (102), the drone, or both, or may be a wired connection corresponding to a connection of the active container (102), the drone, or both (e.g., such as a USB connection that may allow the exchange of data and power). The remote communication device (308) may be a cellular data network transceiver, or may be a wired or wireless connection to a local area network (e.g., such as a local area network at a facility or location proximate to the base station (106)) which itself is coupled to the internet (e.g., the wide area network 806).

The base station (106) also includes a power connection (310) (e.g., a USB connection, a proximity charger) that may be coupled to the active container (102) when it is at the base station (108) in order to charge and/or provide power to the components of the active container. Also included is a power source (316), having similar features and function as the power source (216), which may be a solar panel charger, external battery, or power connection to a local electric grid. The power source (316) may power feature of the base station (106) and may also power features of drones and/or active containers (102) at rest with the base station (106). A base station controller (314) may include a processor and memory and may be configured to manage data bridging features of the base station (106).

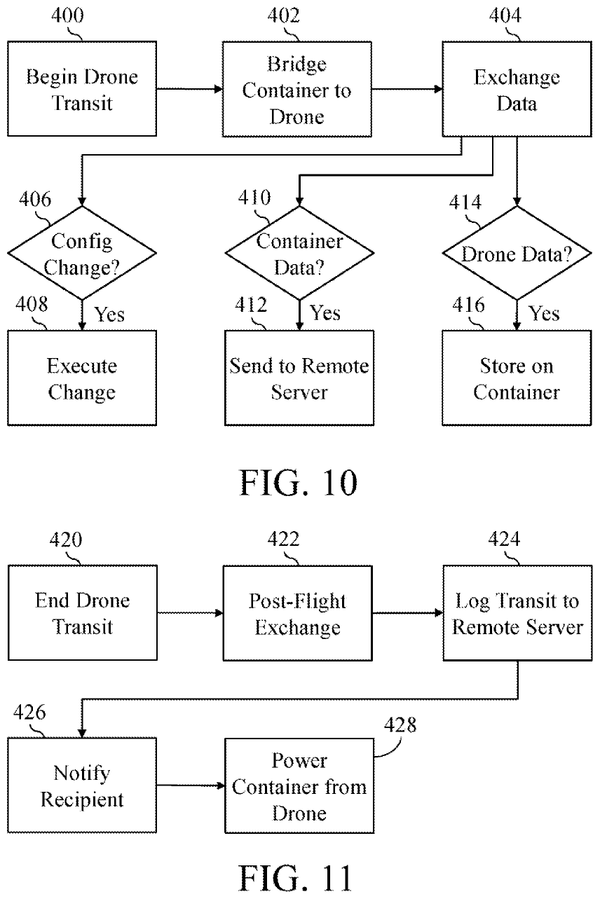

While data bridging has been described in some detail in the context of the system (800) of FIG. 2 and the system (100) of FIG. 7, there are additional features and advantages provided by data bridging with drones. As an example, FIG. 10 is a flowchart showing an exemplary set of steps that could be performed to provide data bridging to a remote network via a drone during transit. The steps of FIG. 10 may be performed with a drone such as the drone (104). When drone transit begins (400), the drone (104) and the active container (102) may be in flight at varying altitudes such that communication via short or medium range wireless transceiver is impossible or unreliable.

During flight, the active container (102) may bridge (402) to the drone (104) via the local communication device (206) (e.g., a Bluetooth connection, a USB connection) in order to allow the exchange of data between the active container (102) and the drone (104). Bridging (402) may be initiated by either device, and may be maintained continuously, may occur intermittently based upon a configured schedule, or may occur on demand such as where a user of the mobile device (810) requests information associated with the active container (102).

Data may then be exchanged (404), which may include the drone (104) providing data to the active container (102) to be stored on the memory (916), the drone (104) providing data to the active container (102) to cause a configuration change based upon data received from a remote party (e.g., a user of the mobile device (810), a process of the server (808)), or may include the active container (102) providing data to the drone (104) to be stored on the storage device (212).

In the case of a configuration change (406) received from a remote party, such information may be received by the drone (104) via the wide area network (806) and transmitted to the active container (102) via the local communication device (206) (e.g., an established Bluetooth pairing). The processor (918) of the active container (102) may then execute (408) the configuration change in order to modify the configuration of a climate control device or other device based upon the received data.

Where exchanged data includes container data (410) from the active container (102) that is provided to the drone (104) via the local communication device (206), such data may be stored on the storage device (212) and then intermittently or immediately provided (412) to a remote server such as the server (808) via the wide area network (806). Data received from the active container (102) may include position data produced by a GPS receiver, temperature or humidity data produced by sensors within the storage compartment (912), and diagnostic, status, or performance data generated by the processor (918) or active system (906), for example.

In some implementations, received data may be combined with data already stored on the storage device (212) prior to sending (412) to the remote server. This may include, for example, combining location and temperature data with data produced by the flight sensors (202) to create a timeline of events associated with the active container (102). As one example of such a timeline, a dataset provided (412) to the remote server may include, for each of a plurality of time periods during transit, a storage compartment temperature, container and/or drone position, speed, active container battery level, drone battery level, any sudden changes in velocity, altitude, or orientation (e.g., provided by accelerometers or gyroscopes of the flight sensors (202)), which may indicate a collision or weather related event, and other similar data.

Where exchanged data includes drone data (414) from the drone (104) that is provided to the active container (102), such data may be stored (416) on the memory (916) of the active container (102) and may also be combined into a corresponding timeline or other dataset, as described above. This may be useful where the drone (104) includes sensor capabilities or produces other relevant data that is not available to the active container (102), in order to create and store a record of such data locally on the active container (102). This may also be useful where, for example, the active container (102) is capable of producing relevant data itself but is configured to disable or throttle such capabilities during transit in order to preserve battery power for climate control or other features. As one example, the active container (102) may include a GPS receiver, but may disable the GPS receiver in order to conserve power when held by the drone (104).

As another example of data bridging associated with drones, FIG. 11 is a flowchart showing an exemplary set of steps that could be performed to provide data bridging to a remote network via a drone upon completion of transit. The steps of FIG. 11 may be performed with a drone such as the drone (104), for example. In some cases, when a drone transit ends (420) and the drone (104) has arrived at the destination of the active container (102), there may be infrastructure or equipment such as the base station (106) to receive the drone (104) and/or the active container (102). However, in other cases the destination may have no equipment or infrastructure for receiving the drone (104), such as where a destination may be a receiving dock at a business or a front porch of an individual. In either case, it may be advantageous to take steps to ensure that the active container (102) is received by the recipient once the flight portion of transit is complete, and that data is available describing the period between the end of the flight portion and the time that receipt is acknowledged or confirmed.

This may include bridging the active container (102) to the drone (104) in order to perform a post-flight exchange of data (422) (e.g., such as the steps FIG. 10). The post-flight exchange may indicate the time that flight ended, the position at which flight ended, and various status data describing the condition of the active container (102) at the time that flight ended (e.g., temperature, battery level, whether any collisions or other events occurred during transit). The produced data may be logged (424) to a remote server (e.g., the server (808)) and associated with a transit or flight completion event in order to describe the final state of the active container (102) and/or drone (104) at the time that the recipient becomes responsible for retrieving the active container (102).

The drone (104), the server (808), or both may also notify (426) a recipient of the drone's (104) arrival and end of the flight portion of transit. Contents of the notification may include some or all of the information that was previously logged (424), and may include real-time position information for the drone (104) and/or active container (102) which may be used by the recipient to track or locate the position of the drone (104) relative to the recipient's current position (e.g., such as by navigating based upon turn-by-turn map directions or viewing an overlaid location of the drone (104) within an augmented reality display on the mobile device (810)). Such information may include an estimate of a period of time during which the active container (102) will be able to maintain the storage compartment (912) at a configured temperature, based upon current battery levels, ambient temperature, and other factors, in order to provide a time frame for taking receipt of the active container (102). Such information may also indicate to the intended recipient that someone else has taken possession of and moved the drone (104) and the active container (102) and may assist the intended recipient in locating the active container (102) after it has been moved.

In some implementations, upon ending drone transit (420) the drone (104) may also be configured to switch into a post-flight power mode where the active container (102) may be powered (428) by the drone (104). For example, where the drone (104) is coupled to the active container (102) via a hardwired connection (e.g., USB) or includes a wireless proximity charger (e.g., an inductive charger), the drone (104) may utilize remaining charge in the battery (204) in order to supplement the power available to the active container (102) until a recipient takes possession of the active container (102). Where the drone (104) includes an additional power source (216) such as a solar panel formed onto the body of the drone (104) or deployable by the drone, powering (428) the active container (102) may include activating or deploying such features (e.g., unfurling and positioning) to provide power instead of or in addition to providing power from the battery (204).

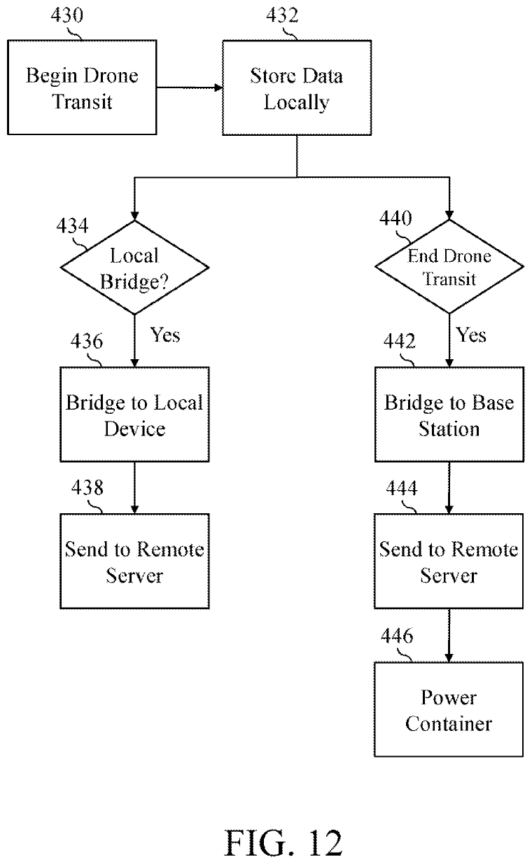

As another example of data bridging, FIG. 12 is a flowchart showing an exemplary set of steps that could be performed to provide data bridging to a remote network via a base station such as the base station (106) or other locally available data bridges. When drone transit begins (430), communication with the wide area network (806) may be unavailable due to the active container (102) or drone lacking such capabilities or, where such capabilities are available, may be undesirable for any reason (e.g., impact on battery, wireless transmission interference with flight systems, local regulations on drone wireless transmissions).

During flight, data generated by systems and sensors of the active container (102), the drone, or both may be stored (432) locally (e.g., on the memory (916), the storage device (212), or both). This may include storing position data from a GPS receiver, temperature data from a sensor within the storage compartment (912), data generated by the flight sensors (202), and other data as has been described. Such data may be stored in various raw formats or may be converted before storage into one or more other formats or data timelines, as has been described.

During transit with a drone, the active container (102) may sometimes be carried within range of a local bridge (434). A local bridge may be a device that is capable of communication with the wide area network (806) and that is capable of communication with the active container (102) or a drone carrying the container via a device such as the local communication device (206) (e.g., Bluetooth, wi-fi). A local bridge may be capable of direct and immediate communication with the wide area network (806) via a cellular data network or wired connection the internet or may capable indirect or intermittent communication with the wide area network (806).

As an example, in some cases the base station (106) may be a local bridge for nearby active containers (102), even when the drone carrying the active container (102) does not land or stop at the base station (106). Rather, as the drone carries the active container (102) during flight, it may pass over the base station (106) at a proximity that allows temporary data bridging via a wi-fi connection. As another example, the drone (104) may be a local bridge for an active container carried by a different drone when they pass each other during flight within a proximity that allows for temporary data bridging.

As another example, public wi-fi networks that are available in some cities or provided by some business locations may provide temporary data bridging when the active container (102) passes within a proximity that allows for connection via wi-fi (e.g., in unobstructed space within which a drone and active container (102) may travel, wireless network devices may be capable of exchanging data at ranges of 300 feet or more).

As another example, a local bridge may be an optical transceiver capable of exchanging data with the active container (102) or drone by projecting and receiving data as infra-red or laser light. Transit of the active container (102) be configured and performed without regard to the availability local bridges or may be configured to regularly position the active container (102) within range of a local bridge, such as where an indirect transit route may be configured that takes the active container (102) within bridging range of one or more of the base stations (106).

As has been described, when within range of a local bridge (434) the active container (102), a drone carrying the container, or both may bridge (436) to the local device so that locally stored data (432) may be provided (438) to a remote server. The content and form of provided (438) data may include any of the examples or variations described herein (e.g., such as in the context of FIG. 10) as well as others that will be apparent to those skilled in the art in light of this disclosure.

When transit with the drone ends (440) at a base station such as the base station (106), the drone may land on, couple with, or otherwise engage the base station (106). A data bridge may then be established (442) through the base station (106) so that locally stored (432) data may be provided (444) to the remote server, as has been described in various other examples. When bridged (442) to the base station, the active container (102) may also be powered by the power source (316) of the base station (106), which may include coupling with the active container (102) via a physical connection (e.g., USB) or proximity charger and providing power to the active container (102) from a local electric grid, solar panel, battery, or other power source. Other actions may also be performed when bridged (442) to the base station, such as creating and storing data related to the completed transit event or notifying a recipient of the active container (102) availability, as described in the context of FIG. 11 and elsewhere.

### III. EXAMPLES

### Example 1

An active container comprising: (a) a storage compartment adapted to store materials during transit; (b) a bridge connection device; (c) a memory operable to store information associated with transit of the active container; and (d) a controller configured to control the operation of the bridge connection device, wherein the controller is further configured to: (i) establish a connection between the bridge connection device and a bridge provider when the bridge connection device detects that the bridge provider is within connectable range of the bridge connection device, (ii) receive a set of transit data from the bridge provider via the bridge connection device, wherein the set of transit data originates from a data stream accessible by the bridge provider, and (iii) store at least a portion of the set of transit data on the memory.

### Example 2

The active container of Example 1, further comprising a temperature management system operable to manage the temperature of the storage compartment and a battery configured to power the temperature management system, wherein the data stream is an internet connection, and wherein the controller is further configured to: (a) transmit a set of temperature data from the temperature management system to a remote server via the bridge connection device, wherein the set of temperature data describes a measured temperature of the storage compartment during transit, and (b) transmit a set of battery data to the remote server via the bridge connection device, wherein the set of battery data describes a measured battery charge of the battery during transit.

### Example 3

The active container of any of Example 1 through 2, wherein the data stream is output from a global positioning device, and wherein the portion of the set of transit data is a global positioning coordinate.

### Example 4

The active container of Example 3, further comprising a tracking system operable to produce global positioning coordinates independently of the data stream.

### Example 5

The active container of any of Examples 1 through 4, wherein the bridge connection device is a low energy Bluetooth transceiver, and wherein the bridge provider is positioned with a vehicle adapted to transport the active container.

### Example 6

The active container of Example 5, further comprising a wireless device operable to access the data stream directly, and a battery configured to operate the wireless device and the low energy Bluetooth transceiver, wherein: (a) the wireless device consumers more electricity during operation than the low energy Bluetooth Transceiver, and (b) the controller is further configured to disable the wireless device when a connection between the low energy Bluetooth transceiver and the bridge provider has been established.

### Example 7

The active container of any of Examples 1 through 6, wherein the controller is further configured to: (a) receive an altitude indicator from a sensor of the active container, (b) determine, based upon the altitude indicator, that the active container is located on an airplane during a communication restricted portion of a flight, and (c) disable a set of restricted devices during the communication restricted portion of the flight, wherein the bridge connection device is within the set of restricted devices.

### Example 8

The active container of Example 7, further comprising a wired bridge connection device, wherein the controller is further configured to: (a) when the set of restricted devices is disabled, establish a connection between the wired bridge connection device and the bridge provider, (b) receive the set of transit data from the bridge provider via the wired bridge connection device, wherein the set of transit data originates, and (c) transmit a set of local transit data via the bridge provider to a remote server.

### Example 9

The active container of any of Examples 1 through 8, further comprising a keypad positioned on the exterior of the active container and an automatic lock configured to selectively prevent or allow access to the storage compartment, the keypad comprising a user input device and an alert indicator, wherein the controller is further configured to: (a) determine whether an alert condition exists based upon the set of transit data, (b) when the alert condition exists, provide an alert indication via the alert indicator and, when the alert condition is critical, operate the automatic lock to prevent access to the storage compartment, (c) receive a set of input from the user input device, (d) determine whether the set of input is valid based upon the portion of the set of transit data, and (e) when the set of input is valid and when the alert condition is not a critical alert condition, operate the automatic lock to allow access to the storage compartment.

### Example 10

The active container of any of Examples 1 through 9, further comprising an automatic lock configured to selectively prevent or allow access to the storage compartment, wherein the controller is further configured to: (a) determine a current location of the active container based upon the portion of the set of transit data, (b) when the connection between the bridge connection device and the bridge provider is lost, access a set of geofence data on the memory and determine whether the current location is within the set of geofence data, and (c) when the current location is outside of the set of geofence data, operate the automatic lock to prevent access to the storage compartment.

### Example 11

A method for bridging an active container to a bridge provider, the method comprising: (a) placing the active container in a vehicle comprising the bridge provider, (b) connecting a bridge connection device of the active container to the bridge provider, wherein connecting the bridge connection device occurs automatically based at least in part on the bridge connection device being within a threshold distance of the bridge provider, (c) receiving, at a controller of the active container, a set of transit data from the bridge provider via the bridge connection device, wherein the set of transit data originates from a data stream accessible by the bridge provider, and (d) storing at least a portion of the set of transit data on a memory of the active container.

### Example 12

The method of Example 11, further comprising: (a) identifying an alert that is associated with the active container based upon the portion of the set of transit data, wherein the alert indicates a risk associated with the safe transit of a material stored in the active container to a recipient, and (b) providing an indication of the alert to a user via an alert indicator positioned on the exterior of the active container.

### Example 13

The method of Example 12, further comprising disconnecting the bridge connection device from the bridge provider, wherein the step of identifying the alert that is associated with the active container occurs after the step of disconnecting the bridge connection device from the bridge provider.

### Example 14

The method of any of Examples 12 through 13, further comprising: (a) determining that the alert is a non-critical alert, and (b) providing the non-critical alert to the user via the alert indicator.

### Example 15

The method of any of Examples 12 through 14, further comprising: (a) determining that the alert is a critical alert, (b) providing the critical alert to the user via the alert indicator, and (c) operating an automatic lock of the active storage container to prevent access to a storage compartment of the active container.

### Example 16

The method of Example 15, wherein determining that the alert is a critical alert further comprises: (a) determine a current location of the active container based upon the portion of the set of transit data, (b) when the connection between the bridge connection device and the bridge provider is lost, access a set of geofence data on the memory and determine whether the current location is within the set of geofence data, and (c) determine that the alert is a critical alert when the current location is not within the set of geofence data.

### Example 17

A data bridging system comprising: (a) an active container comprising a storage compartment adapted to store materials during transit, a bridge connection device, a controller configured to control the operation of the bridge connection device, and a memory configured to store a set of local data associated with the active container, wherein the set of local data comprises a container identifier; (b) a bridge provider configured to: (i) receive data from a global positioning data stream and an internet data stream, (ii) provide data to the active container via the bridge connection device, and (iii) transmit data received from the active container via the internet data stream; and (c) a user device comprising a display, the user device configured to: (i) receive data from the internet data stream, and (ii) store the container identifier; wherein the controller is configured to: (i) establish a connection between the bridge connection device and the bridge provider when the bridge connection device detects that the bridge provider is within connectable range of the bridge connection device, (ii) receive a set of location data from the global positioning data stream and store the set of location data on the memory, (iii) create a container status based upon the set of location data and the set of local data, and (iv) transmit the container status to the user device based upon the container identifier, wherein the container status is configured to cause the user device to display a location of the active container via the display.

### Example 18

The system of Example 17, wherein: (a) the active container further comprises a temperature management system operable to track and maintain the temperature of the storage compartment, (b) the set of local data comprises a set of temperature data produced by the temperature management system, and (c) the container status is configured to cause the user device to display a location of the active container and a temperature of the storage compartment via the display.

### Example 19

The system of any of Examples 17 through 18, wherein the bridge provider is further configured to: (a) receive a set of geofence data associated with the active container via the internet data stream, (b) in response to the bridge connection device disconnecting from the bridge provider, determine a current location of the active container, (c) determine whether the current location is within the set of geofence data, and (i) when the current location is within the set of geofence data, provide an indication to the user device that the active container has arrived at its destination, and (ii) when the current location is not within the set of geofence data, provide an indication to the user device that there is a problem with the active container's delivery.

### Example 20

The system of any of Examples 17 through 19, wherein the active container further comprises an automatic lock configured to selectively prevent or allow access to the storage compartment, wherein the controller is further configured to: (a) determine a current location of the active container based upon the set of location data, (b) when the connection between the bridge connection device and the bridge provider is lost, access a set of geofence data on the memory and determine whether the current location is within the set of geofence data, (c) when the current location is outside of the set of geofence data, operate the automatic lock to prevent access to the storage compartment, and (d) when the current location is inside of the set of geofence data, operate the automatic lock to allow access to the storage compartment.

### Example 21

A data bridging system comprising: (a) an active container comprising a storage compartment, a first local communication device, and a temperature sensor configured to produce temperature data describing the storage compartment; and (b) an aerial drone configured to carry the active container from an origin to a destination along a transit route, the aerial drone comprising a bridge controller, a second local communication device, a global positioning device, and a remote communication device operable to communicate via a wide area network; wherein the bridge controller is configured to, during a flight of the aerial drone: (i) establish communication with the active container by coupling the first local communication device to the second local communication device, (ii) receive a set of active container data from the active container via the second local communication device, wherein the set of active container data comprises a set of temperature data produced by the temperature sensor, (iii) receive a set of position data from the global positioning device, and (iv) provide the set of active container data and the set of position data to a remote server via the remote communication device.

### Example 22

A data bridging system comprising: (a) an active container comprising a storage compartment, a first local communication device, and a temperature sensor configured to produce temperature data describing the storage compartment; (b) an aerial drone configured to carry the active container from an origin to a destination along a transit route, the aerial drone comprising a second local communication device and a global positioning device; and (c) a base station positioned at the destination and adapted to hold the aerial drone, the base station comprising a third local communication device and a bridge controller, wherein the bridge controller is communicatively coupled with a wide area network; wherein the bridge controller is configured to, during a flight of the aerial drone: (i) establish communication with the active container by coupling the third local communication device to the first local communication device, (ii) receive a set of active container data from the active container via the third local communication device, wherein the set of active container data comprises a set of temperature data produced by the temperature sensor during flight to the destination, (iii) establish communication with the aerial drone by coupling the third local communication device to the second local communication device, (iv) receive a set of position data from the aerial drone, wherein the set of position data is produced by the global positioning device during flight to the destination, and (v) provide the set of active container data and the set of position data to a remote server via the wide area network.

Having shown and described various embodiments of the present invention, further adaptations of the methods and systems described herein may be accomplished by appropriate modifications by one of ordinary skill in the art without departing from the scope of the present invention. Several of such potential modifications have been mentioned, and others will be apparent to those skilled in the art. For instance, the examples, embodiments, geometrics, materials, dimensions, ratios, steps, and the like discussed above are illustrative and are not required. As another example, any of the above examples may be combined, in whole or in part, with each other as will be apparent to one skilled in the art in light of this disclosure. Accordingly, the scope of the present invention should be considered in terms of the following claims and is understood not to be limited to the details of structure and operation shown and described in the specification and drawings.

1. An active container comprising:
(a) a storage compartment adapted to store materials during transit;
(b) a bridge connection device;
(c) a memory operable to store information associated with transit of the active container; and
(d) a controller configured to control the operation of the bridge connection device, wherein the controller is further configured to:
(i) establish a connection between the bridge connection device and a bridge provider when the bridge connection device detects that the bridge provider is within connectable range of the bridge connection device,
(ii) receive a set of transit data from the bridge provider via the bridge connection device, wherein the set of transit data originates from a data stream accessible by the bridge provider, and
(iii) store at least a portion of the set of transit data on the memory.

2. The active container of claim 1, further comprising a temperature management system operable to manage the temperature of the storage compartment and a battery configured to power the temperature management system, wherein the data stream is an internet connection, and wherein the controller is further configured to:
(a) transmit a set of temperature data from the temperature management system to a remote server via the bridge connection device, wherein the set of temperature data describes a measured temperature of the storage compartment during transit, and
(b) transmit a set of battery data to the remote server via the bridge connection device, wherein the set of battery data describes a measured battery charge of the battery during transit.

3. The active container of claim 1, wherein the data stream is output from a global positioning device, and wherein the portion of the set of transit data is a global positioning coordinate.

4. The active container of claim 3, further comprising a tracking system operable to produce global positioning coordinates independently of the data stream.

5. The active container of claim 1, wherein the bridge connection device is a low energy Bluetooth transceiver, and wherein the bridge provider is positioned with a vehicle adapted to transport the active container.

6. The active container of claim 5, further comprising a wireless device operable to access the data stream directly, and a battery configured to operate the wireless device and the low energy Bluetooth transceiver, wherein:
(a) the wireless device consumers more electricity during operation than the low energy Bluetooth Transceiver, and
(b) the controller is further configured to disable the wireless device when a connection between the low energy Bluetooth transceiver and the bridge provider has been established.

7. The active container of claim 1, wherein the controller is further configured to:
(a) receive an altitude indicator from a sensor of the active container,
(b) determine, based upon the altitude indicator, that the active container is located on an airplane during a communication restricted portion of a flight, and
(c) disable a set of restricted devices during the communication restricted portion of the flight, wherein the bridge connection device is within the set of restricted devices.

8. The active container of claim 7, further comprising a wired bridge connection device, wherein the controller is further configured to:
(a) when the set of restricted devices is disabled, establish a connection between the wired bridge connection device and the bridge provider,
(b) receive the set of transit data from the bridge provider via the wired bridge connection device, wherein the set of transit data originates, and
(c) transmit a set of local transit data via the bridge provider to a remote server.

9. The active container of claim 1, further comprising a keypad positioned on the exterior of the active container and an automatic lock configured to selectively prevent or allow access to the storage compartment, the keypad comprising a user input device and an alert indicator, wherein the controller is further configured to:
(a) determine whether an alert condition exists based upon the set of transit data,
(b) when the alert condition exists, provide an alert indication via the alert indicator and, when the alert condition is critical, operate the automatic lock to prevent access to the storage compartment,
(c) receive a set of input from the user input device,
(d) determine whether the set of input is valid based upon the portion of the set of transit data, and
(e) when the set of input is valid and when the alert condition is not a critical alert condition, operate the automatic lock to allow access to the storage compartment.

10. The active container of claim 1, further comprising an automatic lock configured to selectively prevent or allow access to the storage compartment, wherein the controller is further configured to:
(a) determine a current location of the active container based upon the portion of the set of transit data,
(b) when the connection between the bridge connection device and the bridge provider is lost, access a set of geofence data on the memory and determine whether the current location is within the set of geofence data, and
(c) when the current location is outside of the set of geofence data, operate the automatic lock to prevent access to the storage compartment.

11. A method for bridging an active container to a bridge provider, the method comprising:
(a) placing the active container in a vehicle comprising the bridge provider,
(b) connecting a bridge connection device of the active container to the bridge provider, wherein connecting the bridge connection device occurs automatically based at least in part on the bridge connection device being within a threshold distance of the bridge provider,
(c) receiving, at a controller of the active container, a set of transit data from the bridge provider via the bridge connection device, wherein the set of transit data originates from a data stream accessible by the bridge provider, and
(d) storing at least a portion of the set of transit data on a memory of the active container.

12. The method of claim 11, further comprising:
(a) identifying an alert that is associated with the active container based upon the portion of the set of transit data, wherein the alert indicates a risk associated with the safe transit of a material stored in the active container to a recipient, and
(b) providing an indication of the alert to a user via an alert indicator positioned on the exterior of the active container.

13. The method of claim 12, further comprising disconnecting the bridge connection device from the bridge provider, wherein the step of identifying the alert that is associated with the active container occurs after the step of disconnecting the bridge connection device from the bridge provider.

14. The method of claim 12, further comprising:
(a) determining that the alert is a non-critical alert, and
(b) providing the non-critical alert to the user via the alert indicator.

15. The method of claim 12, further comprising:
(a) determining that the alert is a critical alert,
(b) providing the critical alert to the user via the alert indicator, and
(c) operating an automatic lock of the active storage container to prevent access to a storage compartment of the active container.

16. The method of claim 15, wherein determining that the alert is a critical alert further comprises:
(a) determine a current location of the active container based upon the portion of the set of transit data,
(b) when the connection between the bridge connection device and the bridge provider is lost, access a set of geofence data on the memory and determine whether the current location is within the set of geofence data, and
(c) determine that the alert is a critical alert when the current location is not within the set of geofence data.

17. A data bridging system comprising:
(a) an active container comprising a storage compartment adapted to store materials during transit, a bridge connection device, a controller configured to control the operation of the bridge connection device, and a memory configured to store a set of local data associated with the active container, wherein the set of local data comprises a container identifier;
(b) a bridge provider configured to:
(i) receive data from a global positioning data stream and an internet data stream,
(ii) provide data to the active container via the bridge connection device, and
(iii) transmit data received from the active container via the internet data stream; and
(c) a user device comprising a display, the user device configured to:
(i) receive data from the internet data stream, and
(ii) store the container identifier;
wherein the controller is configured to:
(i) establish a connection between the bridge connection device and the bridge provider when the bridge connection device detects that the bridge provider is within connectable range of the bridge connection device,
(ii) receive a set of location data from the global positioning data stream and store the set of location data on the memory,
(iii) create a container status based upon the set of location data and the set of local data, and
(iv) transmit the container status to the user device based upon the container identifier, wherein the container status is configured to cause the user device to display a location of the active container via the display.

18. The system of claim 17, wherein:
(a) the active container further comprises a temperature management system operable to track and maintain the temperature of the storage compartment,
(b) the set of local data comprises a set of temperature data produced by the temperature management system, and
(c) the container status is configured to cause the user device to display a location of the active container and a temperature of the storage compartment via the display.

19. The system of claim 17, wherein the bridge provider is further configured to:
(a) receive a set of geofence data associated with the active container via the internet data stream,
(b) in response to the bridge connection device disconnecting from the bridge provider, determine a current location of the active container,
(c) determine whether the current location is within the set of geofence data, and
(i) when the current location is within the set of geofence data, provide an indication to the user device that the active container has arrived at its destination, and
(ii) when the current location is not within the set of geofence data, provide an indication to the user device that there is a problem with the active container's delivery.

20. The system of claim 17, wherein the active container further comprises an automatic lock configured to selectively prevent or allow access to the storage compartment, wherein the controller is further configured to:
(a) determine a current location of the active container based upon the set of location data,
(b) when the connection between the bridge connection device and the bridge provider is lost, access a set of geofence data on the memory and determine whether the current location is within the set of geofence data,
(c) when the current location is outside of the set of geofence data, operate the automatic lock to prevent access to the storage compartment, and
(d) when the current location is inside of the set of geofence data, operate the automatic lock to allow access to the storage compartment.
